(19) United States
(12) Patent Application Publication
(10) Pub. No.: US 2024/0306266 A1
(43) Pub. Date: Sep. 12, 2024

(54) CERAMIC HEATER

(71) Applicant: NGK INSULATORS, LTD., Nagoya-City (JP)

(72) Inventor: Reon TAKANOYA, Handa-City (JP)

(73) Assignee: NGK INSULATORS, LTD., Nagoya-City (JP)

(21) Appl. No.: 18/601,127

(22) Filed: Mar. 11, 2024

Related U.S. Application Data
(63) Continuation of application No. PCT/JP2023/008631, filed on Mar. 7, 2023.

(51) Int. Cl. H05B 3/28

(52) U.S. Cl. CPC H05B 3/283

(57) ABSTRACT

There is provided a ceramic heater including a ceramic plate embedded with a heater electrode; a ceramic shaft on a second surface of the ceramic plate; a shaft hole in a side wall constituting the ceramic shaft, to penetrate through the ceramic shaft; a gas groove in an arc shape on the second surface, and configured to form a gas passage communicating with the shaft hole; gas introduction holes provided in a vertical direction just above the gas groove to communicate therewith, and arranged apart from each other in a longitudinal direction of the gas groove; and lateral holes provided in a lateral direction from the gas introduction holes, and configured to reach a first surface of the ceramic plate. At least one of the gas introduction holes has a diameter different from those of the other gas introduction holes, to uniformize gas flow rates in the gas introduction holes.

### CROSS-REFERENCE TO RELATED APPLICATION

This application is a continuation application of PCT/JP2023/008631 filed Mar. 7, 2023, the entire contents of which are incorporated herein by reference.

### BACKGROUND OF THE INVENTION

### 1. Field of the Invention

The present invention relates to a ceramic heater.

### 2. Description of the Related Art

In a deposition apparatus for a semiconductor manufacturing process, a ceramic heater is used as a supporting stage for uniformly controlling a temperature of a wafer. As such a ceramic heater, a ceramic heater including a ceramic plate on which a wafer is to be placed, and a cylindrical ceramic shaft attached to the ceramic plate is widely used.

During a manufacturing process of a semiconductor device, process gas flows to a bottom surface of the wafer placed on the ceramic heater to generate deposits in some cases. To prevent the process gas from flowing to the bottom surface of the wafer, a method in which a purge function is provided to a ceramic heater with a shaft is known. The purge function is a function of ejecting inert gas to an outer peripheral portion of the ceramic plate, thereby preventing the process gas from flowing to the bottom surface of the wafer.

Ceramic heaters with a shaft that have the purge function and various structures have been proposed. For example, Patent Literature 1 (JP2022-147715A) discloses an electrode-embedded member that includes a plate-like base made of ceramic including a placement surface, and an electrode embedded in the base. The base internally includes gas grooves formed in at least two layers parallel to the placement surface, communication holes making the gas grooves in the adjacent layers communicate with each other, a plurality of discharge holes discharging gas from a first-layer gas groove closest to the placement surface to outside, and a supply hole supplying gas from the outside to a second-layer gas groove farthest from the placement surface. Patent Literature 2 (JP2007-46141A) discloses a heating device that includes a base made of ceramic and embedded with a resistance heating body and a tubular member supporting the base. The base includes gas injection ports provided on a substrate heating surface, a gas providing passage provided at a center on a bottom surface of the base, and gas passages provided inside the base so as to make the gas providing passage and the gas injection ports to communicate with each other.

### CITATION LIST

### Patent Literature

Patent Literature 1: JP2022-147715A
Patent Literature 2: JP2007-46141A

### SUMMARY OF THE INVENTION

As described above, the method in which the purge function is provided to a ceramic heater with a shaft is known. FIGS. 4A to 4D illustrate an example of such an existing ceramic heater with a shaft. A ceramic heater 110 illustrated in FIG. 4A includes a ceramic plate 112 embedded with a heater electrode 124, and a ceramic shaft 114 attached to the ceramic plate 112, and heater rods 126 connected to the heater electrode 124 extend through an internal space S of the ceramic shaft 114. A shaft hole 116 is provided in a side wall constituting the ceramic shaft 114, to penetrate through the ceramic shaft 114 from one end to the other end. On the other hand, a gas groove 118 is provided in an arc shape on a surface of the ceramic plate 112 on the ceramic shaft 114 side, and the gas groove 118 and an upper end surface of the ceramic shaft 114 form a gas passage communicating with the shaft hole 116. In the ceramic plate 112, a plurality of gas introduction holes 120 provided in a vertical direction just above the gas groove 118 to communicate with the gas groove 118 are arranged apart from each other in a longitudinal direction of the gas groove 118. On the other hand, lateral holes 122 are provided in a direction from the respective gas introduction holes 120 toward an outer periphery of the ceramic plate 112 and reach an outer peripheral portion of the ceramic plate 112. In such a configuration, gas supplied to the shaft hole 116 is ejected to the outer peripheral portion of the ceramic plate 112 through the shaft hole 116, the gas groove 118, the plurality of gas introduction holes 120, and the plurality of lateral holes 122 in order. However, as can be seen from FIG. 4D, distances from the shaft hole 116 to the plurality of gas introduction holes 120 are different from each other. Therefore, difference in flow rates of the gas transmitted to the gas introduction holes 120 is large, and difference in gas amounts finally ejected from the lateral holes 122 is also large.

The present inventers recently found that at least one of the gas introduction holes is caused to have a diameter different from a diameter of each of the other gas introduction holes, which makes it possible to uniformize the gas amounts ejected from the plurality of lateral holes.

Therefore, an object of the present invention is to provide a ceramic heater with a shaft that has a purge function and can uniformize gas amounts ejected from a plurality of lateral holes.

The present invention provides the following aspects.

### [Aspect 1]

A ceramic heater comprising:
a disk-like ceramic plate including a first surface on which a wafer is to be placed, and a second surface opposite to the first surface, and embedded with a heater electrode;
a cylindrical ceramic shaft attached on the second surface of the ceramic plate;
a shaft hole provided in a side wall constituting the ceramic shaft, to penetrate through the ceramic shaft from one end to another end;
a gas groove provided in an arc shape on the second surface of the ceramic plate, and configured to form, together with an upper end surface of the ceramic shaft, a gas passage communicating with the shaft hole;
a plurality of gas introduction holes provided in a vertical direction just above the gas groove to communicate with the gas groove in the ceramic plate, and arranged apart from each other in a longitudinal direction of the gas groove; and
a plurality of lateral holes provided in a direction from the plurality of gas introduction holes toward an outer periphery of the ceramic plate in the ceramic plate, and configured to reach the first surface or a side end surface of the ceramic plate,
wherein the ceramic heater is configured to, in a case where gas is supplied to the shaft hole, enable the gas to be purged from the first surface or the side end surface of the ceramic plate through the shaft hole, the gas groove, the gas introduction holes, and the lateral holes in order, and
wherein at least one of the gas introduction holes has a diameter different from a diameter of each of the other gas introduction holes, to uniformize gas flow rates in the plurality of gas introduction holes.

### [Aspect 2]

The ceramic heater according to aspect 1, wherein the gas groove is provided in the arc shape having a center angle of 270 degrees to 330 degrees.

### [Aspect 3]

The ceramic heater according to aspect 1 or 2, wherein the shaft hole is positioned at a center in the longitudinal direction of the gas groove.

### [Aspect 4]

The ceramic heater according to any one of aspects 1 to 3, wherein at least one of the gas introduction holes positioned in a region not belonging to a vicinity of the shaft hole or vicinities of both ends of the gas groove has a diameter greater than a diameter of each of the gas introduction holes positioned in the vicinity of the shaft hole and the gas introduction holes positioned in the vicinities of both ends of the gas groove.

### [Aspect 5]

The ceramic heater according to any one of aspects 1 to 4, wherein at least one of the gas introduction holes positioned in a region not belonging to a vicinity of the shaft hole or vicinities of both ends of the gas groove has a diameter greater by 10% or more than a diameter of each of the gas introduction holes positioned in the vicinity of the shaft hole and the gas introduction holes positioned in the vicinities of both ends of the gas groove.

### [Aspect 6]

The ceramic heater according to aspect 4 or 5, wherein the number of the gas introduction holes having the greater diameter is two.

### [Aspect 7]

The ceramic heater according to any one of aspects 1 to 6,
wherein the number of the plurality of gas introduction holes is six,
wherein the shaft hole is positioned between third and fourth gas introduction holes from one end of the gas passage, and
wherein second and fifth gas introduction holes from the one end of the gas passage each have a diameter greater by 10% or more than a diameter of each of the other gas introduction holes.

### [Aspect 8]

The ceramic heater according to any one of aspects 1 to 7, wherein the lateral holes reach the first surface of the ceramic plate.

### [Aspect 9]

The ceramic heater according to any one of aspects 1 to 7, wherein the lateral holes reach the side end surface of the ceramic plate.

### [Aspect 10]

The ceramic heater according to any one of aspects 1 to 9, wherein the lateral holes are provided obliquely to the first surface, to come close to or reach the first surface as approaching the outer periphery of the ceramic plate.

### [Aspect 11]

The ceramic heater according to any one of aspects 1 to 10, wherein the lateral holes are partially configured in the vertical direction to reach the first surface.

### BRIEF DESCRIPTION OF THE DRAWINGS

FIG. 1A is a top view schematically illustrating an aspect of a ceramic heater according to the present invention.

FIG. 1B is a cross-sectional view of the ceramic heater illustrated in FIG. 1A, taken along line 1B-1B, where although a shaft hole 16 does not essentially appear in the cross-section taken along line 1B-1B, the shaft hole 16 is virtually drawn for description of positional relationship.

FIG. 1C is a cross-sectional view of the ceramic heater illustrated in FIG. 1A, taken along line 1C-1C.

FIG. 1D is a cross-sectional view of the ceramic heater illustrated in FIG. 1B, taken along line 1D-1D, where although the shaft hole 16 does not essentially appear in the cross-section taken along line 1D-1D, the shaft hole 16 is virtually drawn for description of positional relationship.

FIG. 2 is a cross-sectional view schematically illustrating another aspect of the ceramic heater according to the present invention, where although the shaft hole 16 does not essentially appear in the cross-section, the shaft hole 16 is virtually drawn for description of positional relationship.

FIG. 3 is a cross-sectional view schematically illustrating still another aspect of the ceramic heater according to the present invention, where although the shaft hole 16 does not essentially appear in the cross-section, the shaft hole 16 is virtually drawn for description of positional relationship.

FIG. 4A is a top view schematically illustrating an example of an existing ceramic heater.

FIG. 4B is a cross-sectional view of the existing ceramic heater illustrated in FIG. 4A, taken along line 4B-4B, where although a shaft hole 116 does not essentially appear in the cross-section taken along line 4B-4B, the shaft hole 116 is virtually drawn for description of positional relationship.

FIG. 4C is a cross-sectional view of the existing ceramic heater illustrated in FIG. 4A, taken along line 4C-4C.

FIG. 4D is a cross-sectional view of the existing ceramic heater illustrated in FIG. 4B, taken along line 4D-4D, where although the shaft hole 116 does not essentially appear in the cross-section taken along line 4D-4D, the shaft hole 116 is virtually drawn for description of positional relationship.

### DETAILED DESCRIPTION OF THE INVENTION

A ceramic heater according to the present invention is a stand, made of ceramic, for supporting a wafer while controlling a temperature of the wafer in a semiconductor manufacturing apparatus. Typically, the ceramic heater according to the present invention may be a ceramic heater for a semiconductor deposition apparatus. Typical examples of the deposition apparatus include a CVD (chemical vapor deposition) apparatus (for example, thermal CVD apparatus, plasma CVD apparatus, optical CVD apparatus, and MOCVD apparatus) and a PVD (physical vapor deposition) apparatus.

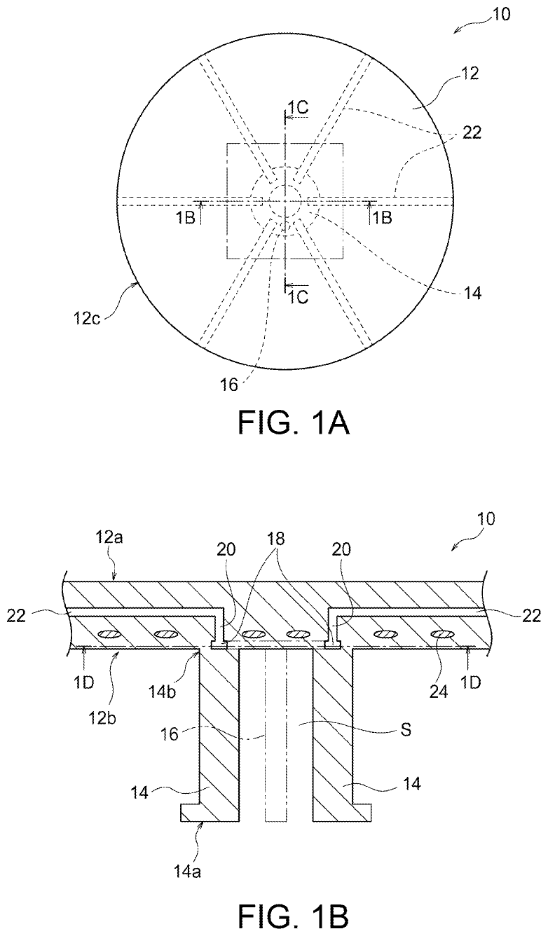

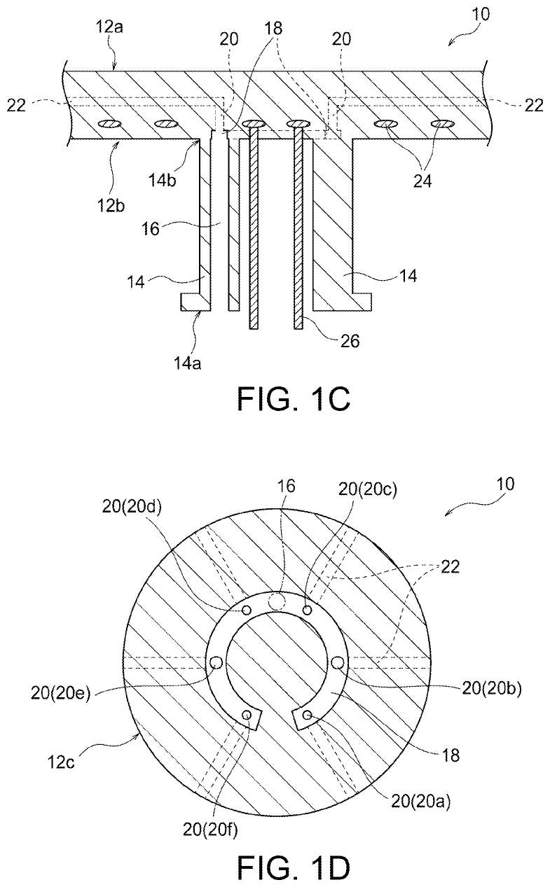

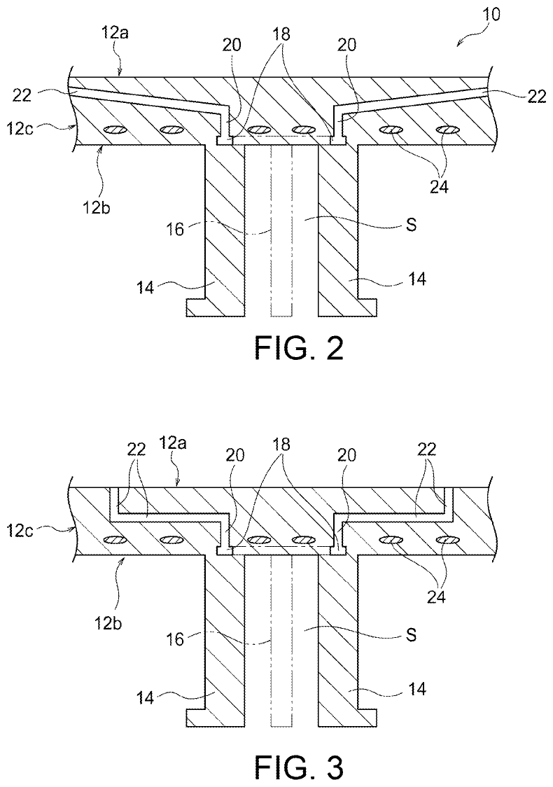

FIGS. 1A to 1D illustrate an aspect of the ceramic heater. A ceramic heater 10 illustrated in FIGS. 1A to 1D and 2 includes a disk-like ceramic plate 12, a cylindrical ceramic shaft 14, a shaft hole 16, a gas groove 18, a plurality of gas introduction holes 20, and a plurality of lateral holes 22. A heater electrode 24 is embedded in the ceramic plate 12. The ceramic plate 12 includes a first surface 12a on which a wafer (not illustrated) is to be placed, and a second surface 12b opposite to the first surface 12a. The ceramic shaft 14 is attached to the second surface 12b. The shaft hole 16 is provided in a side wall constituting the ceramic shaft 14, to penetrate through the ceramic shaft 14 from one end to the other end. The gas groove 18 is provided in an arc shape on the second surface 12b of the ceramic plate 12, and the gas groove 18 and an upper end surface of the ceramic shaft 14 form a gas passage communicating with the shaft hole 16. In the ceramic plate 12, the plurality of gas introduction holes 20 are provided in a vertical direction just above the gas groove 18 to communicate with the gas groove 18. The gas introduction holes 20 are arranged apart from each other in a longitudinal direction of the gas groove 18. In the ceramic plate 12, the plurality of lateral holes 22 are provided in a direction from the plurality of gas introduction holes 20 toward an outer periphery of the ceramic plate 12. The lateral holes 22 reach the first surface 12a or a side end surface 12c of the ceramic plate 12. Accordingly, the ceramic heater 10 is configured to, in a case where gas is supplied to the shaft hole 16, enable the gas to be purged from the first surface 12a or the side end surface 12c of the ceramic plate 12 through the shaft hole 16, the gas groove 18, the gas introduction holes 20, and the lateral holes 22 in order. At least one of the gas introduction holes 20 has a diameter different from a diameter of each of the other gas introduction holes 20 so as to uniformize gas flow rates in the plurality of gas introduction holes 20. As described above, at least one of the gas introduction holes 20 is caused to have the diameter different from the diameter of each of the other gas introduction holes 20, which makes it possible to uniformize gas amounts ejected from the plurality of lateral holes 22.

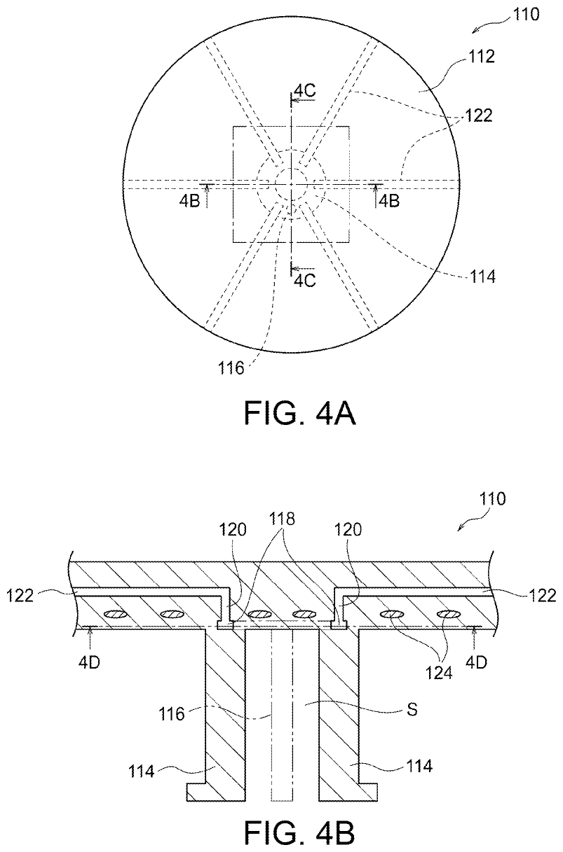

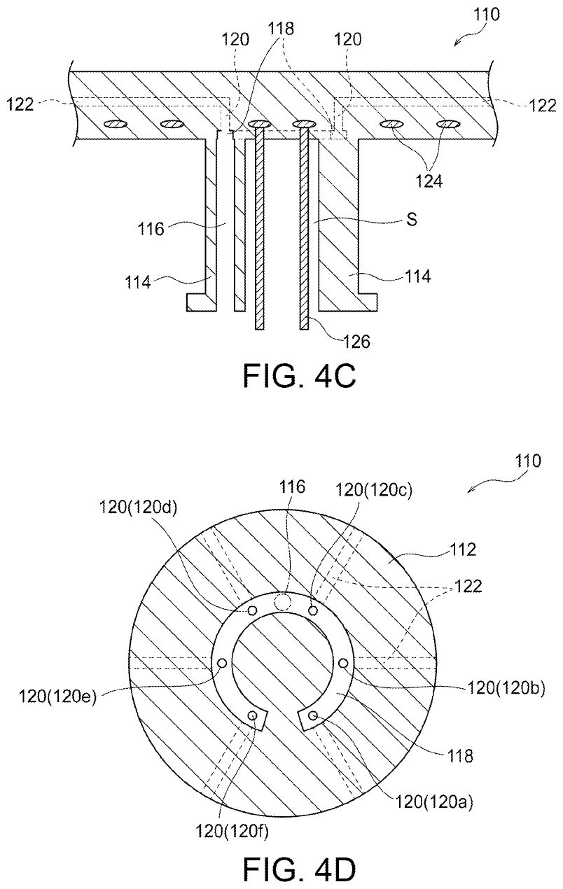

As described above, in the existing ceramic heater 110 having the gas purge function, the distances from the shaft hole 116 to the plurality of gas introduction holes 120 are different from each other as can be seen from FIG. 4D. Therefore, the difference in flow rates of the gas transmitted to the gas introduction holes 120 is large, and the difference in gas amounts finally ejected from the lateral holes 122 is also large. In other words, the gas amounts ejected from the plurality of lateral holes 122 are nonuniform. However, to sufficiently exert the purge function for preventing the process gas from flowing to the bottom surface of the wafer, it is desirable to uniformize the gas amounts ejected to the outer peripheral portion of the ceramic plate as much as possible. In this respect, according to the present invention, at least one of the gas introduction holes 20 is caused to have the diameter different from the diameter of each of the other gas introduction holes 20, which makes it possible to uniformize the gas amounts ejected from the plurality of lateral holes 22.

The configuration of the ceramic plate 12 is not particularly limited except for the configurations of the gas groove 18, the gas introduction holes 20, and the lateral holes 22, and the ceramic plate 12 may have a configuration similar to a configuration of a ceramic plate adopted in a well-known ceramic heater.

Main portions (namely, ceramic base) of the ceramic plate 12 other than the gas groove 18, the gas introduction holes 20, the lateral holes 22, and the heater electrode 24 are preferably made of aluminum nitride in terms of excellent heat conductivity, high electrical insulation property, thermal expansion characteristics close to silicon, and the like.

A preferable shape of the ceramic plate 12 is a disk shape. However, it is unnecessary for the disk-like ceramic plate 12 to have a complete circular shape in a planar view, and the disk-like ceramic plate 12 may have a partially-lacked incomplete circular shape, for example, an orientation flat shape. A size of the ceramic plate 12 is appropriately determined based on a diameter of a wafer assumed to be used and is not particularly limited. In a case of the circular shape, however, the diameter is typically 150 mm to 450 mm, and for example, about 300 mm.

Protrusions (not illustrated) may be provided on the first surface 12a of the ceramic plate 12. The protrusions are preferably arranged with equal intervals on the first surface 12a of the ceramic plate 12. A shape of each of the protrusions is not particularly limited, but is preferably a columnar shape. A diameter of each of the protrusions is not particularly limited, but is preferably 0.1 mm to 8 mm, more preferably 0.5 mm to 5 mm, further preferably 0.5 mm to 4 mm, and particularly preferably 0.70 mm to 2.54 mm. The protrusions are preferably shaped integrally with the ceramic plate 12 by embossing or the like. Therefore, the protrusions are also preferably made of aluminum nitride as with the ceramic plate 12. A height of each of the protrusions is not particularly limited, but is preferably 0.001 mm to 0.1 mm, more preferably 0.005 mm to 0.08 mm, further preferably 0.01 mm to 0.05 mm, and particularly preferably 0.01 mm to 0.03 mm. A distance between center axes of the protrusions adjacent to each other is preferably 4 mm to 30 mm, more preferably 5 mm to 26 mm, further preferably 7 mm to 26 mm, and particularly preferably 7 mm to 15 mm.

As illustrated in FIGS. 1B and 1C, the heater electrode 24 is embedded in the ceramic plate 12. Although not particularly limited, the heater electrode 24 may be, for example, an electrically conductive coil wired like a line drawn with a single stroke over an entire surface of the ceramic plate 12. Heater rods 26 for power feeding are connected to respective ends of the heater electrode 24, and the heater rods 26 are connected to a heater power supply (not illustrated) through an internal space S of the ceramic shaft 14. When power is supplied from the heater power supply, the heater electrode 24 generates heat to heat the wafer placed on the first surface 12a. The heater electrode 24 is not limited to the coil, and may be, for example, a ribbon (long thin plate) or a mesh.

An internal electrode other than the heater electrode 24 may be embedded in the ceramic plate 12. Examples of such an internal electrode include an ESC electrode and an RF electrode. The ESC electrode is an abbreviation for an electrostatic chuck (ESC) electrode, and is also referred to as an electrostatic electrode. The ESC electrode is preferably a circular thin-layer electrode slightly smaller in diameter than the ceramic plate 12, and may be, for example, a mesh-like electrode formed by weaving thin metal wires into a net shape to be a sheet shape. The ESC electrode may be used as a plasma electrode. In other words, when a high-frequency wave is applied to the ESC electrode, the ESC electrode can be used as the plasma electrode, and deposition by a plasma CVD process is performable. An ESC rod for power feeding is preferably connected to the ESC electrode, and the ESC rod is preferably connected to an external power supply (not illustrated) through the internal space S of the ceramic shaft 14. When a voltage is applied by the external power supply, the ESC electrode chucks the wafer placed on the first surface 12a. Chucking force at this time is Johnson Rahbeck force because a volume resistivity of aluminum nitride that may constitute the main portions of the ceramic plate 12 is 1×10⁸ Ωcm to 1×10¹³ Ωcm.

As illustrated in FIGS. 1B and 1C, the ceramic shaft 14 is a cylindrical shaft attached to the second surface 12b of the ceramic plate 12, and may have a configuration similar to a configuration of a ceramic shaft adopted in a well-known ceramic heater. The ceramic shaft 14 includes the internal space S for housing the heater rods 26. The ceramic shaft 14 is preferably made of a ceramic material similar to the ceramic material of the ceramic plate 12. Therefore, the ceramic shaft 14 is preferably made of aluminum nitride. The upper end surface of the ceramic shaft 14 is preferably joined with the second surface 12b of the ceramic plate 12 by solid-phase joining or diffusion joining. An outer diameter of the ceramic shaft 14 is not particularly limited, and is, for example, about 40 mm. An inner diameter (diameter of internal space S) of the ceramic shaft 14 is also not particularly limited, and is, for example, about 36 mm.

As illustrated in FIGS. 1B and 1C, the shaft hole 16 is provided in the side wall constituting the ceramic shaft 14, to penetrate through the ceramic shaft 14 from one end (for example, lower end surface 14a) to the other end (for example, upper end surface 14b). The shaft hole 16 is typically provided in parallel to a center axis of the ceramic shaft 14. A diameter of the shaft hole 16 is not particularly limited, but is preferably 4.5 mm to 5.5 mm, and more preferably 4.8 mm to 5.2 mm. A planar view of the shaft hole 16 may be an optional shape such as a circular shape and a polygonal shape, but is preferably a circular shape. The number of shaft holes 16 provided in the ceramic shaft 14 may be two or more, but is preferably one. This is because the gas supplied from one shaft hole 16 can be distributed to the lateral holes 22 through the gas groove 18 and the gas introduction holes 20. From such a viewpoint, the shaft hole 16 is preferably positioned at a center in the longitudinal direction (namely, direction along arc) of the gas groove 18. This makes it possible to equally distribute and supply the gas from the shaft hole 16 toward both ends of the gas groove 18.

The gas groove 18 is provided in an arc shape on the second surface 12b of the ceramic plate 12 as illustrated in FIG. 1D, and forms, together with the upper end surface 14b of the ceramic shaft 14, the gas passage communicating with the shaft hole 16 as illustrated in FIGS. 1B and 1C. In other words, the gas groove 18 functions as the gas passage for supplying the gas supplied from the shaft hole 16 to the plurality of gas introduction holes 20. The gas groove 18 can be provided in an arc shape, a center angle of which is preferably 270 degrees to 330 degrees, more preferably 280 degrees to 320 degrees, further preferably 290 degrees to 310 degrees, and for example, 300 degrees. The center angle means, when the gas groove 18 is regarded as an arc in a planar view, an angle formed by a side connecting one end of the arc and a center of a circle including the arc, and a side connecting the other end of the arc and the center of the circle (namely, center angle of fan shape including arc). A cross-sectional shape of the gas groove 18 is typically a rectangular shape, but may be the other optional shape and is not particularly limited.

As illustrated in FIGS. 1B to 1D, the gas introduction holes 20 are a plurality of holes provided in the vertical direction just above the gas groove 18 to communicate with the gas groove 18 in the ceramic plate 12, and are arranged apart from each other in the longitudinal direction (namely, direction along arc) of the gas groove 18. A diameter of each of the gas introduction holes 20 is not particularly limited, but is preferably 0.5 mm to 5.0 mm, and more preferably 1.0 mm to 3.0 mm. As illustrated in FIG. 1D, at least one (preferably two holes 20b and 20e) of the gas introduction holes 20 has the diameter different from the diameter of each of the other gas introduction holes 20 (for example, 20a, 20c, 20d, and 20f) so as to uniformize the gas flow rates in the plurality of gas introduction holes 20. In a case where the diameters of the gas introduction holes 120 are all equal to each other as illustrated in FIG. 4D, the gas flow rates supplied to the gas introduction holes 120 are varied based on the distances from the shaft hole 116 from which the gas is supplied, and do not become uniform. For example, in the existing example illustrated in FIG. 4D, a large amount of gas flows into holes 120cand 120d positioned in a vicinity of the shaft hole 116 from which the gas is supplied, but a small amount of gas flows into holes 120b and 120e separated from the shaft hole 116. However, a large amount of gas flows into holes 120a and 120f positioned in vicinities of both ends of the gas groove 118 due to stoppage of the gas flow at both ends of the gas groove 118. Therefore, as illustrated in FIG. 1D, at least one (preferably, two holes 20b and 20e) of the gas introduction holes 20 is caused to have the diameter different from the diameter of each of the other gas introduction holes 20 (for example, holes 20a, 20c, 20d, and 20f), which makes it possible to uniformize the gas flow rates in the plurality of gas introduction holes 20 (for example, holes 20a, 20b, 20c, 20d, 20e, and 20f). Note that “uniformization of gas flow rates” used herein does not mean that the gas flow rates are completely made equal to each other, but means that difference among the gas flow rates in the plurality of gas introduction holes 20 is reduced to bring the gas flow rates in the plurality of gas introduction holes 20 close to uniform (namely, correct nonuniformity).

Therefore, a diameter D₁ of at least one (for example, holes 20b and 20e) of the gas introduction holes 20 positioned in regions not belonging to the vicinity of the shaft hole 16 or the vicinities of both ends of the gas groove 18 is preferably greater than a diameter D₂ of each of the gas introduction holes 20 (for example, holes 20c and 20d) positioned in the vicinity of the shaft hole 16 and the gas introduction holes 20 (for example, holes 20a and 20f) positioned in the vicinities of both ends of the gas groove. More specifically, the above-described diameter D₁ is preferably greater by 10% or more, more preferably greater by 10% to 20%, further preferably greater by 10% to 15% than the above-described diameter D₂. The number of gas introduction holes 20 (for example, holes 20b and 20e) having the greater diameter D₁ is preferably two. In this case, as illustrated in FIG. 1D, the gas introduction holes 20 are arranged symmetrically to the shaft hole 16 positioned at the center in the longitudinal direction of the gas groove 18, which makes it possible to easily realize uniformization of the flow rates. Further, the diameters of the gas introduction holes 20 are not limited to two types as illustrated in FIG. 1D, and may be three or more types. The diameters of the gas introduction holes 20 may be individually set so as to further uniformize the gas flow rates, based on the number and positions of gas introduction holes 20.

The number of gas introduction holes 20 is not particularly limited, but is preferably six to ten, more preferably six to eight, and most preferably six as illustrated in FIG. 1D. In this case, the shaft hole 16 is positioned between third and fourth gas introduction holes 20 (namely, holes 20c and 20d) from one end of the gas passage, and second and fifth gas introduction holes 20 (namely, holes 20b and 20e) from the one end of the gas passage each preferably have the diameter greater by 10% or more than the diameter of each of the other gas introduction holes (namely, holes 20a, 20c, 20d, and 20f). With this configuration, the gas can be fed to the six lateral holes 22 at the uniformized flow rates even though the number of gas introduction holes 20 is relatively small. This makes it possible to efficiently uniformize the gas flow rates ejected to the outer peripheral portion of the ceramic plate 12.

The lateral holes 22 are provided in the direction from the gas introduction holes 20 toward the outer periphery of the ceramic plate 12 in the ceramic plate 12, and reach the first surface 12a or the side end surface 12c of the ceramic plate 12. The lateral holes 22 may be configured to reach the side end surface 12c of the ceramic plate 12, or may be configured to reach the first surface 12a of the ceramic plate 12. Further, as illustrated in FIG. 2, the lateral holes 22 may be provided obliquely to the first surface 12a so as to come close to or reach the first surface 12a as approaching the outer periphery of the ceramic plate 12. Alternatively, as illustrated in FIG. 3, the lateral holes 22 may be partially configured in the vertical direction so as to reach the first surface 12a.

As desired, an annular member for gas purge (not illustrated) is provided along the outer periphery of the ceramic plate 12. The annular member includes many ejection ports so as to uniformly eject the gas supplied from outlets of the lateral holes 22 toward desired positions of the outer peripheral portion of the ceramic plate 12. It is intended that a user of the ceramic heater 10 actually arranges a desired annular member on the outer periphery of the ceramic plate 12 in use.

The ceramic heater 10 is configured to, in the case where the gas is supplied to the shaft hole 16, enable the gas to be purged from the first surface 12a or the side end surface 12c of the ceramic plate 12 through the shaft hole 16, the gas groove 18, the gas introduction holes 20, and the lateral holes 22 in order. With this configuration, the wafer is placed on the first surface 12a. Supplying the gas to the bottom surface of the wafer makes it possible to eject inert gas to the outer peripheral portion of the ceramic plate and to prevent the process gas from flowing to the bottom surface of the wafer. This makes it possible to prevent the process gas from flowing to the bottom surface of the wafer placed on the ceramic heater and to prevent deposits from being generated during a manufacturing process (in particular, deposition process) of a semiconductor device. The gas supplied to the shaft hole 16 is preferably inert gas excellent in heat transfer property, and particularly preferably He gas.

What is claimed is:

1. A ceramic heater comprising:
a disk-like ceramic plate including a first surface on which a wafer is to be placed, and a second surface opposite to the first surface, and embedded with a heater electrode;
a cylindrical ceramic shaft attached on the second surface of the ceramic plate;
a shaft hole provided in a side wall constituting the ceramic shaft, to penetrate through the ceramic shaft from one end to another end;
a gas groove provided in an arc shape on the second surface of the ceramic plate, and configured to form, together with an upper end surface of the ceramic shaft, a gas passage communicating with the shaft hole;
a plurality of gas introduction holes provided in a vertical direction just above the gas groove to communicate with the gas groove in the ceramic plate, and arranged apart from each other in a longitudinal direction of the gas groove; and
a plurality of lateral holes provided in a direction from the plurality of gas introduction holes toward an outer periphery of the ceramic plate in the ceramic plate, and configured to reach the first surface or a side end surface of the ceramic plate,
wherein the ceramic heater is configured to, in a case where gas is supplied to the shaft hole, enable the gas to be purged from the first surface or the side end surface of the ceramic plate through the shaft hole, the gas groove, the gas introduction holes, and the lateral holes in order, and
wherein at least one of the gas introduction holes has a diameter different from a diameter of each of the other gas introduction holes, to uniformize gas flow rates in the plurality of gas introduction holes.

2. The ceramic heater according to claim 1, wherein the gas groove is provided in the arc shape having a center angle of 270 degrees to 330 degrees.

3. The ceramic heater according to claim 1, wherein the shaft hole is positioned at a center in the longitudinal direction of the gas groove.

4. The ceramic heater according to claim 1, wherein at least one of the gas introduction holes positioned in a region not belonging to a vicinity of the shaft hole or vicinities of both ends of the gas groove has a diameter greater than a diameter of each of the gas introduction holes positioned in the vicinity of the shaft hole and the gas introduction holes positioned in the vicinities of both ends of the gas groove.

5. The ceramic heater according to claim 1, wherein at least one of the gas introduction holes positioned in a region not belonging to a vicinity of the shaft hole or vicinities of both ends of the gas groove has a diameter greater by 10% or more than a diameter of each of the gas introduction holes positioned in the vicinity of the shaft hole and the gas introduction holes positioned in the vicinities of both ends of the gas groove.

6. The ceramic heater according to claim 4, wherein the number of the gas introduction holes having the greater diameter is two.

7. The ceramic heater according to claim 1,
wherein the number of the plurality of gas introduction holes is six,
wherein the shaft hole is positioned between third and fourth gas introduction holes from one end of the gas passage, and
wherein second and fifth gas introduction holes from the one end of the gas passage each have a diameter greater by 10% or more than a diameter of each of the other gas introduction holes.

8. The ceramic heater according to claim 1, wherein the lateral holes reach the first surface of the ceramic plate.

9. The ceramic heater according to claim 1, wherein the lateral holes reach the side end surface of the ceramic plate.

10. The ceramic heater according to claim 1, wherein the lateral holes are provided obliquely to the first surface, to come close to or reach the first surface as approaching the outer periphery of the ceramic plate.

11. The ceramic heater according to claim 1, wherein the lateral holes are partially configured in the vertical direction to reach the first surface.
